(19) United States
(12) Patent Application Publication
(10) Pub. No.: US 2025/0357262 A1
(43) Pub. Date: Nov. 20, 2025

(54) PACKAGE ASSEMBLY AND MANUFACTURING METHOD THEREOF

(71) Applicant: Taiwan Semiconductor Manufacturing Company, Ltd., Hsinchu (TW)

(72) Inventors: Wensen Hung, Hsinchu County (TW); Wei-Kong Sheng, Hsinchu (TW); Tsung-Yu Chen, Hsinchu City (TW); Cheng-Hung Lin, New Taipei City (TW); Meng-Tsan Lee, Hsinchu (TW)

(73) Assignee: Taiwan Semiconductor Manufacturing Company, Ltd., Hsinchu (TW)

(21) Appl. No.: 18/665,586

(22) Filed: May 16, 2024

(51) Int. Cl. H01L 23/427; H01L 23/00; H01L 23/367; H01L 25/00; H01L 25/065

(52) U.S. Cl. CPC H01L 23/427; H01L 21/50; H01L 23/3675; H01L 23/3733; H01L 23/3735; H01L 24/32; H01L 25/105; H01L 2224/32245

(57) ABSTRACT

A package assembly includes a device package, a ring structure, and a lid on the ring structure. The device package includes a package substrate, a first die coupled to the package substrate, and a second die aside the first die and coupled to the package substrate. The ring structure is on the package substrate and surrounds the first and second dies. The lid is thermally coupled to the first die and includes a vapor chamber, a working fluid in the vapor chamber, a wicking structure in the vapor chamber, first and second pillars distributed in the vapor chamber. The first pillars are coated with a first powder layer. The second pillars are directly over the first die, and the first and second pillars are arranged in a staggered manner.

### BACKGROUND

In the packaging of integrated circuits, semiconductor dies may be stacked through bonding, and may be bonded to other package components such as interposers and package substrates. The resulting semiconductor packages are known as three-dimensional integrated circuits (3DICs). However, warpage, coplanarity, delamination, and heat dissipation issues are challenges in the 3DICs. As a result, there is continuous effort in developing new mechanisms of forming package assemblies with better reliability and performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic cross-sectional view of a vapor chamber lid, in accordance with some embodiments.

FIG. 1B is a schematic bottom view of an upper portion of a vapor chamber lid, in accordance with some embodiments.

FIG. 1C is a fragmentary cross-sectional view of the structure in the dashed box 1C of FIG. 1A, in accordance with some embodiments.

FIG. 1D is another fragmentary cross-sectional view of the structure in the dashed box 1C of FIG. 1A, in accordance with some embodiments.

FIG. 1E is a fragmentary cross-sectional view of the structure in the dashed box 1E of FIG. 1A, in accordance with some embodiments.

FIG. 1F is a fragmentary cross-sectional view of the structure in the dashed box 1F of FIG. 1A, in accordance with some embodiments.

FIG. 1G is a schematic top view of a lower portion of a vapor chamber lid, in accordance with some embodiments.

FIGS. 2A-2C are schematic cross-sectional views of various stages of manufacturing a package assembly, in accordance with some embodiments.

FIG. 3 is a schematic cross-sectional view of a package module, in accordance with some embodiments.

FIGS. 4A and 4C are schematic cross-sectional views of various stages of manufacturing a package assembly, in accordance with some embodiments.

FIG. 4B is a schematic top view of the structure shown in FIG. 4A, in accordance with some embodiments.

FIGS. 5, 6, and 7A are schematic cross-sectional views of variations of a package assembly, in accordance with some embodiments.

FIGS. 7B and 7C are schematic top view of variations of the package assembly shown in FIG. 7A, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A typical problem with 3DICs is heat dissipation during operation. This problem may become severe if the dies which generate a lot of heat (e.g., a central processing unit (CPU) die, a graphics processing unit (GPU) die, and/or the like) are included in the 3DICs. As such, thermal solutions for high power applications using high performance processors are needed. Embodiments discussed herein are to provide a package assembly including a heat dissipating lid and methods for forming the same. The intermediate stages of forming the package assembly are illustrated, and the variations of the embodiments are discussed. According to some embodiments, the heat dissipating lid is thermally coupled to the device package, and thermal energy generated by the device package may be dissipated through the lid. For example, the lid with high thermal conductivity helps spread the heat generated from the device package over a larger area. In an embodiment, the lid includes the working fluid contained in the vapor chamber, and the working fluid frequently vaporizes and condenses to form a circulation to expel the heat generated by the device package. This arrangement may effectively spread thermal energy across the lid, such that heat generated by the device package may be dissipated in an efficient manner.

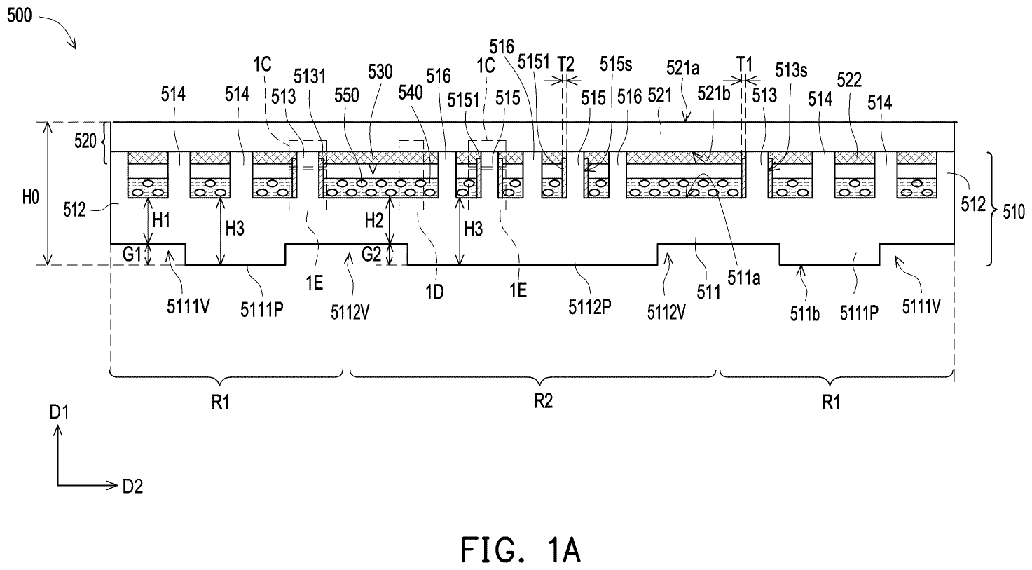

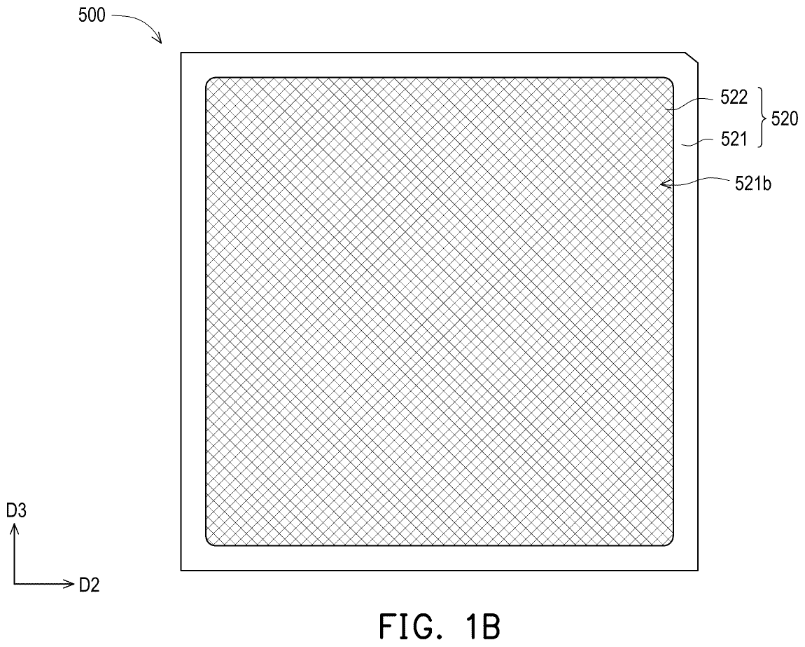

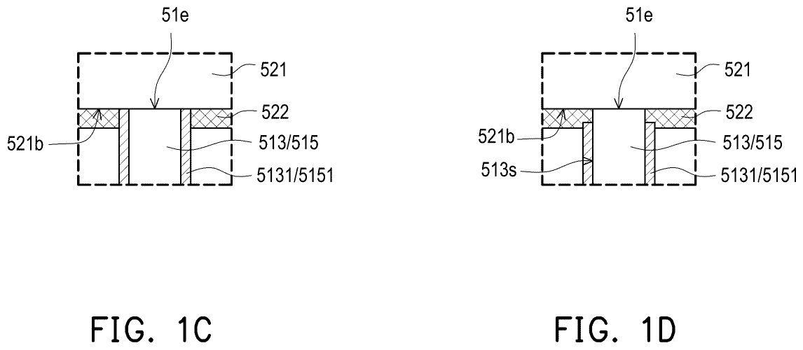

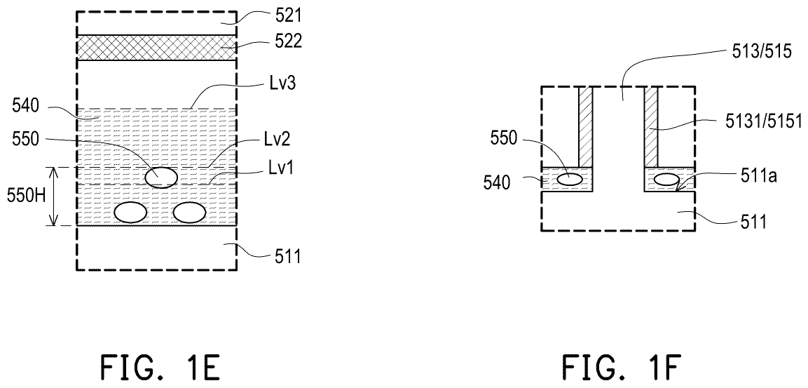

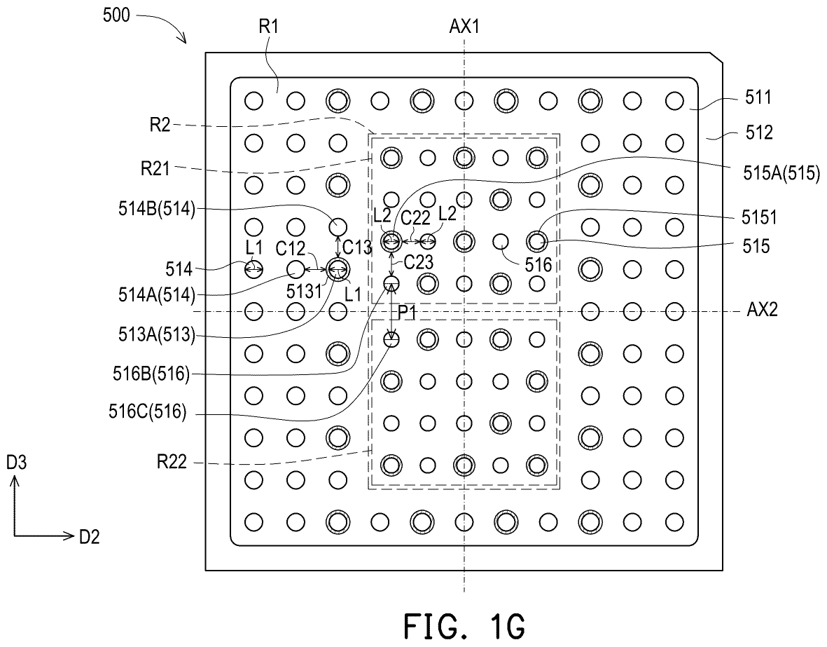

FIG. 1A is a schematic cross-sectional view of a vapor chamber lid, FIG. 1B is a schematic bottom view of an upper portion of a vapor chamber lid, FIG. 1C is a fragmentary cross-sectional view of the structure in the dashed box 1C of FIG. 1A, FIG. 1E is a fragmentary cross-sectional view of the structure in the dashed box 1E of FIG. 1A, FIG. 1F is a fragmentary cross-sectional view of the structure in the dashed box 1F of FIG. 1A, and FIG. 1G is a schematic top view of a lower portion of a vapor chamber lid, in accordance with some embodiments. It should be noted that throughout the various views and illustrative embodiments, like reference numbers are used to designate like elements.

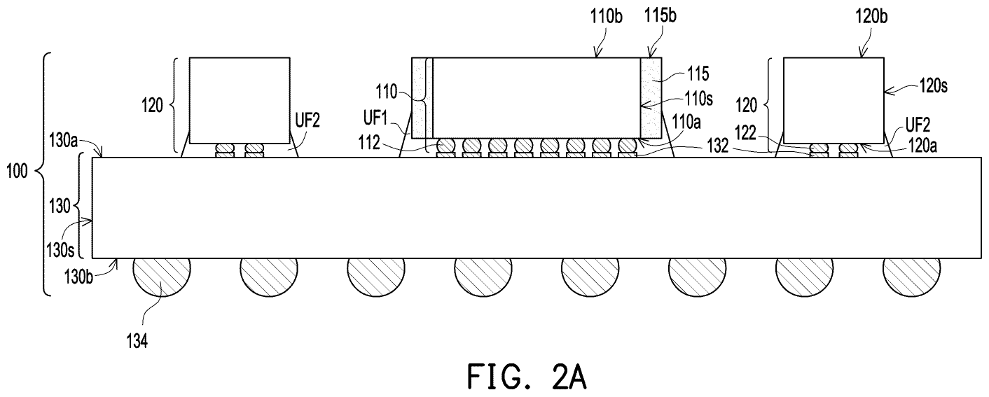

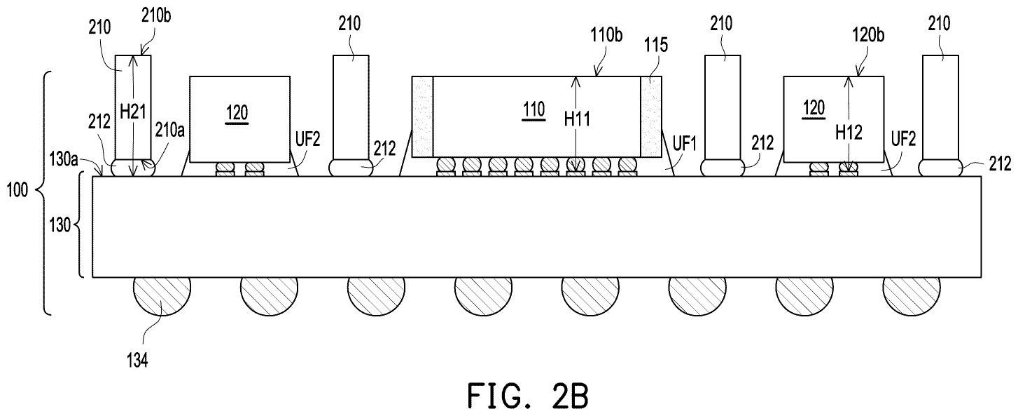

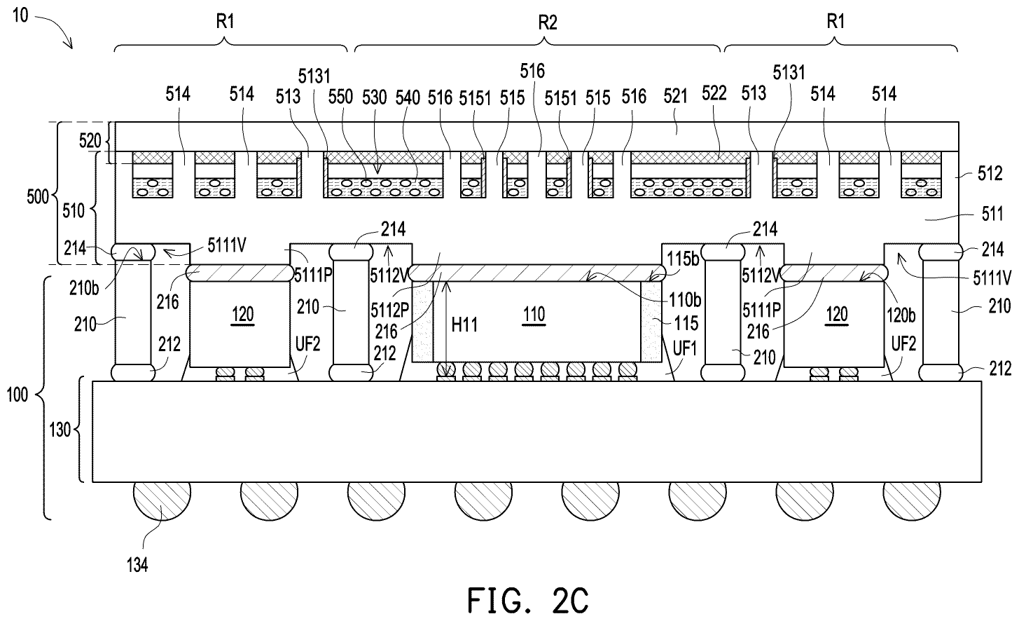

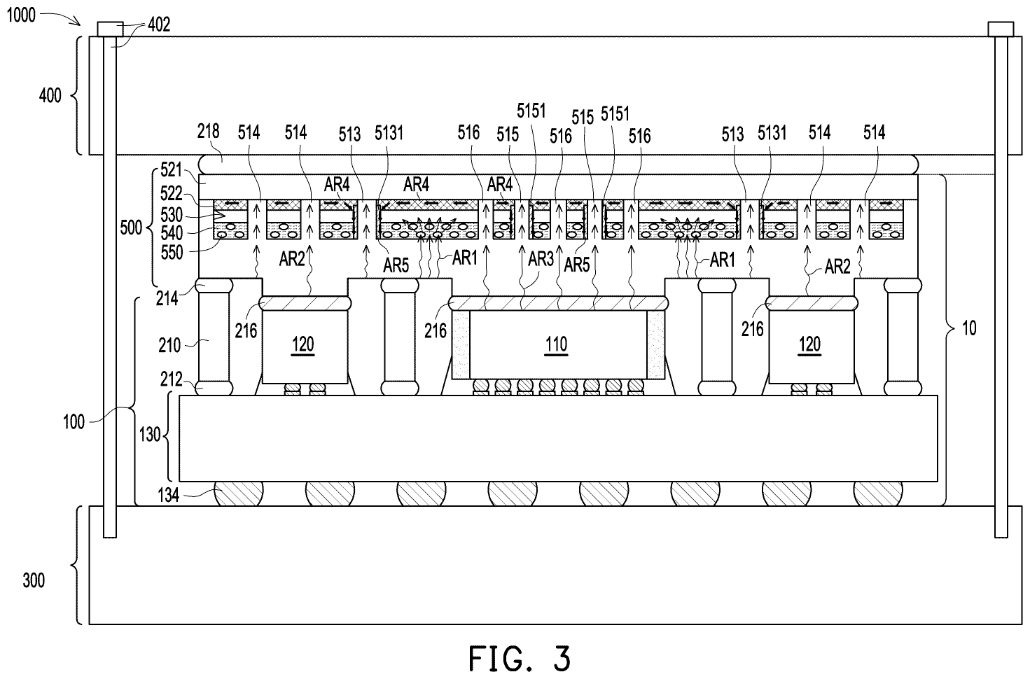

Referring to FIG. 1A, a vapor chamber (VC) lid 500 is provided. The VC lid 500 may be configured to facilitate heat dissipation of the device package to be coupled (see FIG. 2C and FIG. 3). The VC lid 500 may be viewed as a heat-dissipating lid. In some embodiments, the VC lid 500 includes a lower portion 510 and an upper portion 520 overlying and bonded to the lower portion 510. For example, the lower portion 510 includes a bottom plate 511 and a chamber wall 512 extending along a first direction D1 (e.g., a height (or thickness) direction of the VC lid 500), and the chamber wall 512 is on the periphery of the bottom plate 511. The material(s) of the bottom plate 511 may include copper, aluminum, cobalt, copper coated with nickel, stainless steel SUS430, tungsten, copper-tungsten, copper-molybdenum, silver diamond, copper diamond, metal diamond composites, aluminum nitride, aluminum silicon carbide, alloy42, diamond like carbon, single crystal diamond, the like, combinations thereof, etc. Other suitable thermally conductive material(s) may be used. In some embodiments, the thermal conductivity of the material of the bottom plate 511 is in a range of about 100 W/mK and about 2000 W/mK. The bottom plate 511 and the chamber wall 512 and may (or may not) be integratedly formed. The chamber wall 512 may have the same material as the bottom plate 511 or may include a different material than the bottom plate 511.

The bottom plate 511 may include an upper surface 511a facing the upper portion 520 and a lower surface 511b opposite to the upper surface 511a. In some embodiments, the upper surface 511a is smoother than the lower surface 511b, where the lower surface 511b may include one or more topographic feature(s). For example, at least one groove (e.g., 5111V and 5112V) is recessed from the lower surface 511b. The configuration of the groove(s) may provide stress relief for stress incurred during attaching the VC lid 500 to the device package (see FIG. 2C). For example, a groove 5111V is located within a first region R1 of the VC lid 500, and a groove 5112V is located within a second region R2 of the VC lid 500. The first region R1 may overlap the peripheral region of the lower surface 511b, and the second region R2 may overlap the central region of the lower surface 511b.

With continued reference to FIG. 1A, the groove 5111V may have a depth G1 measured along the first direction D1, where the depth G1 is in a range of about 0.5 mm and about 1.5 mm. The groove 5112V may have a depth G2 measured along the first direction D1, where the depth G2 may be in a range of about 0.5 mm and about 1.5 mm. The depths (G1 and G2) may be substantially equal or may be different. The depth G1 may depend on the overall height of the device package to be coupled (see FIG. 2C). In some embodiments, the maximum thickness H0 of the VC lid 500 measured along the first direction D1 is in a range of about 2.0 mm and about 10.0 mm. The ratio of the depth (G1 or G2) to the maximum thickness H0 may be in a range of about 0.05 and 0.75. It is realized that the dimensions herein are merely examples, and may be changed to other suitable values.

With continued reference to FIG. 1A, the bottom plate 511 may include varying thicknesses measured along the first direction D1. For example, a portion of the bottom plate 511 having a thickness H1 corresponds to the first region R1 in which the groove 5111V is formed, and a portion of the bottom plate 511 having a thickness H2 corresponds to the second region R2 in which the groove 5112V is formed. The thickness(es) (H1 and/or H2) may be in a range of about 0.5 mm and about 2.0 mm. The thicknesses (H1 and H2) may be substantially equal or may be different, depending on the corresponding depths (G1 and G2). The thicknesses (H1 and H2) are less than a thickness H3, where the third thickness H3 may be viewed as the maximum thickness of the bottom plate 511 measured between the upper surface 511a and the lower surface 511b. For example, the thickness H3 is in a range of about 0.5 mm and about 3.0 mm. In an embodiment in which the lower surface 511b is planar without the groove, the thicknesses (H1, H2, and H3) may be the same.

In another aspect, the bottom plate 511 includes one or more protrusions (e.g., 5111P and 5112P) encircled by the grooves (5111V and 5112V). For example, a protrusion 5111P is located within the first region R1 and between the grooves (5111V and the 5112V), where the thickness of the protrusion 5111P may correspond to the depth G1. A protrusion 5112P may be located within the second region R2 and surrounded by the groove 5112V, where the thickness of the protrusion 5112P may correspond to the depth G2. The grooves and protrusions may have a different configuration than shown, and the distributions of the grooves and protrusions may depend on the configuration of the device package to be coupled (see FIG. 2C) and the product requirements. This will be discussed later in accompanying with FIG. 2C.

In some embodiments, the lower portion 510 includes pillars (513, 514, 515, and 516) distributed over the bottom plate 511. For example, the pillars (513 and 514) are located within the first region R1, and the pillars (515 and 516) are located within the second region R2. The pillars (513-516) may be positioned at various locations to reinforce the mechanical strength of the VC lid 500 and/or help thermal management of the VC lid 500. The pillars (513-516) may include one or more material(s) such as nickel, copper, aluminum, stainless-steel, titanium, polymers, silver, phosphorous alloys, the like, combinations thereof, etc. The materials of the bottom plate 511 and the pillars (513-516) may be substantially the same or may be different. In some embodiments, the pillars (513-516) are formed on the upper surface 511a of the bottom plate 511 by any suitable deposition process. Alternatively, the pillars (513-516) are pre-formed and then placed on the bottom plate 511 through any suitable bonding process. In some embodiments, the lateral dimensions of the pillars (513 and 514) are greater than the lateral dimensions of the pillars (515 and 516). It is appreciated that without placing the pillars on the first region R1, large voids in the vapor chamber reduce the mechanical strength of the VC lid 500 and result in a pop-corning effect during thermal cycles or after reliability tests, leading to reliability issues and/or package failure. By including the pillars (513 and 514) having the larger size in the first region R1, such voids can be reduced in size and the mechanical strength of the VC lid 500 may be improved.

With continued reference to FIG. 1A, the respective pillar 513 may be coated with a powder layer 5131. The respective pillar 515 may be coated with a powder layer 5151. The material(s) of the powder layer(s) (5131 and/or 5151) may include nickel powders, copper powders, aluminum powders, stainless-steel powders, titanium powders, polymer powders, silver powders, phosphorous alloy powders, the like, combinations thereof, etc. The materials of the powder layers (5131 and 5151) may be the same or may be different. In an embodiment, the materials of the powder layer 5131 and the corresponding pillar 513 are substantially the same, and the materials of the powder layer 5151 and the corresponding pillar 515 are substantially the same. The powder layer 5131 formed on the sidewall 513s of the corresponding pillar 513 may have a thickness T1 measured along a second direction D2, where the second direction D2 is substantially perpendicular to the first direction D1. The powder layer 5151 formed on the sidewall 515s of the respective pillar 515 may have a thickness T2 measured along the second direction D2. The thickness(es) (T1 and/or T2) may be in a range of about 0.2 mm and about 5.0 mm. It is realized that the thicknesses are merely examples, and may be changed to other suitable values. The configuration of the pillars coated with the powder layers (5131 and 5151) may help accelerate the return flow of working fluid as will be discussed later in accompanying with FIG. 3. The dimension/distribution details of the pillars will be discussed later in accompanying with FIG. 1G.

Referring to FIG. 1B and with reference to FIG. 1A, the upper portion 520 may include a top plate 521 having an upper surface 521a and a lower surface 521b opposite to the upper surface 521a and facing the lower portion 510. The material(s) of the top plate 521 may be selected from the same candidate material(s) for forming the bottom plate 511. The materials of the top plate 521 and the bottom plate 511 may be substantially the same or may be different. In some embodiments, the upper portion 520 includes a mesh 522 on the lower surface 521b of the top plate 521. The material(s) of the mesh 522 may include copper, aluminum, cobalt, copper coated with nickel, stainless steel SUS 430, tungsten, copper-tungsten, copper-molybdenum, silver diamond, copper diamond, metal diamond composites, aluminum nitride, aluminum silicon carbide, alloy 42, diamond like carbon, single crystal diamond, the like, combinations thereof, etc. The mesh 522 may have any suitable size and shape to provide for circulation of working fluid within the VC lid 500.

Referring to FIGS. 1C-1D and with reference to FIG. 1A, the upper portion 520 covers and is connected to the lower portion 510. For example, the top plate 521 is bonded to the bottom plate 511 and the chamber wall 512 through direct metal-to-metal (e.g., Cu— to —Cu) bonding or any suitable bonding technique(s). The respective pillar (513-516) may have an upper end 51F bonded to the top plate 521 and the mesh 522 through direct metal-to-metal (e.g., Cu-to-Cu) bonding or any suitable bonding technique(s). In some embodiments, the powder layer 5131 partially covers the sidewall 513s of the corresponding pillar 513 and may not be in contact with the lower surface 521b of the top plate 521, as shown in FIG. 1D. In alternative embodiments, the powder layer 5131 fully covers the sidewall 513s of the corresponding pillar 513 and is in physical contact with the mesh 522 and the lower surface 521b of the top plate 521, as shown in FIG. 1C. The pillar 515 with the powder layer 5151 may have the same/similar configuration as the pillar 513 with the powder layer 5131, so that the details thereof are not repeated herein.

With reference to FIG. 1A, the bottom plate 511, the chamber wall 512, and the top plate 521 may enclose, hermetically seal, and define a vapor chamber 530 within the VC lid 500. The vapor chamber 530 may contain an evaporating and condensing liquid (e.g., a two-phase vaporizable liquid) serving as a working fluid 540 for the VC lid 500. The working fluid 540 may be a liquid (e.g., water, methyl alcohol, propylene glycol, the like, etc.) that changes phase within the vapor chamber 530 to disperse heat away from the device package to be coupled. For example, during the operation, the working fluid 540 evaporates adjacent to the bottom of the vapor chamber 530 and condenses adjacent to the top plate 521 at the top of the vapor chamber 530. In some embodiments, the VC lid 500 includes a wicking structure 550 housed within the vapor chamber 530. For example, the wicking structure 550 is configured to transfer the working fluid 540 through capillary action. The wicking structure 550 may be or include a layer of powder, and the material(s) of the powder used for the wicking structure 550 may be selected from the same candidate material(s) for forming the powder layer 5131/5151 or the mesh 522. The wicking structure 550 may include any suitable microporous layer or meshed/porous structure, depending on a desired capillary performance.

Referring to FIG. 1E and with reference to FIG. 1A, the vapor chamber 530 may be filled with a desired amount of the working fluid 540. For example, the vapor chamber 530 contains 0.5 grams to 10 grams of the working fluid 540. It is realized that the volumes are merely examples and may be changed to other suitable values. In an embodiment where the working fluid 540 is at low liquid level, the wicking structure 550 is partially soaked in the working fluid 540 (see level Lv1 in FIG. 1E). In an embodiment where the working fluid 540 is at middle/high liquid level, the wicking structure 550 is fully soaked in the working fluid 540 (see level Lv2 and level Lv3). The wicking structure 550 may have a height (or thickness) 550H to provide sufficient fluid transportation and avoid increasing the weight of the resulting package assembly. The filling rate of the working fluid 540 is associated with the height 550H of the wicking structure 550. For example, the ratio of the filling rate of the working fluid 540 to the height 550H of the wicking structure 550 is in a range of about 30% and 150%. Other ratio range may be possible depending on the heat dissipation requirements.

Referring to FIG. 1F and with reference to FIG. 1A, the powder layer 5131 may partially cover the sidewall 513s of the corresponding pillar 513 and may be separated from the upper surface 511a of the bottom plate 511, as shown in FIG. 1F. As the working fluid 540 is at low/middle liquid level, the powder layer 5131 may (or may not) be in contact with the working fluid 540. In alternative embodiments, the powder layer 5131 fully covers the sidewall 513s of the corresponding pillar 513 and is in physical contact with the upper surface 511a of the bottom plate 511, as shown in FIG. 1A. The pillar 515 with the powder layer 5151 may have the same/similar configuration as the pillar 513 with the powder layer 5131, so that the details thereof are not repeated herein.

FIG. 1G shows the distribution of the pillars (513-516) on the bottom plate 511. Referring to FIG. 1G and with reference to FIG. 1A, the respective pillar 513 arranged in the first region R1 may have a lateral dimension L1 greater than a lateral dimension L2 of the respective pillar 515 arranged in the second region R2. For example, the lateral dimension L1 is in a range of about 0.5 mm and about 5.0 mm, such as about 3.0 mm. The lateral dimension L2 may be in a range of about 0.5 mm and about 5.0 mm, such as about 2.5 mm. In some embodiments, the distribution of the pillars (515 and 516) per unit area is greater than the distribution of the pillars (513 and 514) per unit area. For example, the pillars (515 and 516) are arranged in a denser manner within the second region R2 than the pillars (513 and 514) distributed in the first region R1. Since the second region R2 may correspond to the hot spot region in the resulting structure, by arranging the pillars (515 and 516) in a denser manner may facilitate heat-dissipation in the resulting structure. In some embodiments, the density of the pillars (513 and 514) within the second region R2 is about 1.5 to 6 times greater than that of the pillars (513 and 514) within the first region R1.

In some embodiments, the pillars 513 coated with the powder layer 5131 and the pillars 514 are alternately arranged in a loop along the boundary of the second region R2 or along an array of the pillars (515 and 516). For example, the pillar 514 is positioned between adjacent two of the pillars 513 which are coated with the powder layer 5131 in both of the second and third directions (D2 and D3), where the second and third directions (D2 and D3) are substantially perpendicular to each other. Besides those pillars 514 arranged between the pillars 513, the rest of the pillars 514 may be distrusted over the rest space of the first region R1. For example, the pillar 513A coated with the powder layer 5131 is distanced from a closest pillar 514A by a spacing C12 measured along the second direction D2 and is distanced from another closest pillar 514B by a spacing C13 measured along the third direction D3. The spacing C12 and the spacing C13 may be substantially equal or may be different. The spacing C12 (or the spacing C13) may be in a range of about 1 mm and about 10 mm. It is realized that the ranges of the spacing are merely examples, and may be changed to other suitable values.

With continued reference to FIG. 1G, the second region R2 may include a first zone R21 and a second zone R22 disposed side-by-side along the third direction D3. One or more dies having hot spots (or high-power-consuming/high performance dies) included in the device package may correspond to the first zone R21 and the second zone R22 after coupling the VC lid 500 to the device package (see FIG. 2C). In some embodiments, the pillars 515 coated with the powder layer 5151 correspond to (or are arranged in proximity to) the hot spots of the die (e.g., the first die 110). The pillars (515 and 516) distributed in the first zone R21 may be arranged in a mirror-symmetrical configuration with respective to a virtual axis AX1 in the top view, where the virtual axis AX1 is substantially parallel to the third direction D3. The pillars (515 and 516) distributed in the first zone R21 and in the second zone R21 may be arranged in a mirror-symmetrical configuration with respective to a virtual axis AX2 in the top view, where the virtual axis AX2 is substantially parallel to the second direction D2. The mirror-symmetrical configuration may be the configuration with respective to the arrays of the pillars (515 and 516). The arrangement of the array of the pillars (515 and 516) may essentially be mapped on the bottom plate 512 by reflection, vice versa.

Still referring to FIG. 1G, the pillars 515 coated with the powder layer 5151 and the pillars 516 in the first zone R21 (or the second zone R22) may be alternately arranged in both of the second and third directions (D2 and D3). Such staggered arrangement may maintain (or improve) temperature uniformity across the die (e.g., the first die 110) corresponding to the second region R2. In some embodiments, the pillar 515A coated with the powder layer 5151 is distanced from a closest pillar 516A by a spacing C22 measured along the second direction D2 and is distanced from another closest pillar 514B by a spacing C23 measured along the third direction D3. The spacing C22 and the spacing C23 may be substantially equal or may be different. The spacing C22 (or the spacing C23) may be in a range of about 1.0 mm and about 10.0 mm. It is realized that the ranges of the spacing are merely examples, and may be changed to other suitable values. In some embodiments, a pitch P1 is between the pillar 516B in the first zone R21 and the closet pillar 516C in the second zone R22. The pitch P1 may be in a range of about 1 mm and about 10 mm. The pitch P1 may use other suitable values. In some embodiments, a ratio of the pitch P1 to the spacing C22 (or the spacing C23) is about 1.5 to about 2.

FIGS. 2A-2C are schematic cross-sectional views of various stages of manufacturing a package assembly, in accordance with some embodiments. Like reference numbers are used to designate like elements. Referring to FIG. 2A, a device package 100 is provided. The device package 100 may include one or more dies (e.g., 110 and 120) disposed on and electrically coupled to a package component 130. It is noted that the dies (e.g., 110 and 120) and the package component 130 illustrated herein are merely for illustrative purposes, and additional or fewer element(s) may be arranged in each of the dies (e.g., 110 and 120) and the package component 130. The dies (e.g., 110 and 120) may be singulated from one or more device wafer(s). The dies (e.g., 110 and/or 120) may (or may not) be packaged before coupling to the package component 130. In some embodiments where the dies (e.g., 110 and/or 120) have been packaged through any suitable packaging process before coupling to the package component 130, the packaged dies (e.g., 110 and/or 120) may be referred to as a die package. The term “die” used herein may be referred to a singulated die without being packaged or may be referred to a die package.

In some embodiments, at least one first die 110 is encapsulated by an insulating encapsulation 115. The first die 110 may include a first side 110a facing the package component 130, a second side 110b opposite to the first side 110a, and a sidewall 110s connected to the first side 110a and the second side 110b. In some embodiments, the first die 110 includes die connectors 112 (e.g., micro-bumps, metal pillars with or without caps, controlled collapse chip connection (C4) bumps, or the like) distributed at the first side 110a for electrically connecting the package component 130. In some embodiments, an interposer (not individually shown) is interposed between the first die 110 and the package component 130 to electrically connect the first die 110 to the package component 130.

In some embodiments, the insulating encapsulation 115 extends along the sidewall 110s of the first die 110. The insulating encapsulation 120 may be or include molding compound, epoxy resin, molding underfill, and/or the like, and may be applied by compression molding, transfer molding, etc. A thinning process (e.g., a chemical-mechanical polishing (CMP) process, a grinding process, an etching process, a combination thereof, and/or the like) may be performed on the second side 110b of the first die 110 and the insulating encapsulation 115, such that the upper surface 115b of the insulating encapsulation 115 and the second side 110b of the first die 110 may be substantially leveled (or coplanar) with one another, within process variations. In some embodiments, an underfill layer UF1 may be formed between the gap of the first die 110 and the package component 130 to laterally cover the electrical connections of the die connectors 112 and the package component 130. As a sufficient amount of the underfill material is dispensed, a portion of the underfill layer UF1 may climb up to partially (or fully) cover the outer sidewall of the insulating encapsulation 115. Alternatively, the underfill layer UF1 is omitted.

With continued reference to FIG. 2A, one or more second die(s) 120 may be coupled to the package component 130 and disposed at opposing sides of the first die 110. The respective second die 120 may include a first side 120a facing the package component 130, a second side 120b opposite to the first side 120a, and a sidewall 120s connected to the first side 120a and the second side 120b. In some embodiments, the respective second die 120 includes die connectors 122 (e.g., micro-bumps, metal pillars with or without caps, C4 bumps, or the like) distributed at the first side 120a for electrically connecting the package component 130. In some embodiments, an underfill layer UF2 may be formed between the gap of the respective second die 120 and the package component 130 to laterally cover the electrical connections of the die connectors 122 and the package component 130. As a sufficient amount of the underfill material is dispensed, a portion of the underfill layer UF2 may climb up to partially (or fully) cover the sidewall 120s of the respective second die 120. Alternatively, the underfill layer UF2 is omitted.

Each of the first die 110 and the second dies 120 may have a single function (e.g., a logic die, a processor die (e.g., a central processing unit (CPU) die, a graphics processing unit (GPU) die, an application-specific integrated circuit (ASIC) die, etc.), a memory die (e.g., a dynamic random-access memory (DRAM) die, a static random-access memory (SRAM) die, a stacked memory module, a high-bandwidth memory (HBM) die, etc.), a RF die, a mixed signal die, a I/O die, combinations thereof, and/or the like). A plurality of first dies 110 (or the second dies 120) may have different sizes (e.g., footprint areas) and/or has different functions. In some embodiments, at least one of the first die 110 and the second dies 120 is formed as a die stack having multiple functions (e.g., a system-on-chip or the like). In an embodiment, the first die 110 includes a logic die and the second dies 120 include memory dies. In an embodiment, the first die 110 includes high performance dies (or high-power-consuming dies) which may generate a lot of heat during the operation. In an embodiment, during the operation, the first die 110 consumes more power, and hence generates more heat, than the respective second die 120. For example, the thermal energy generated from the first die 110 is greater than the thermal energy generated from the respective second die 120. The first die 110 may include one or more hot spot(s), where the hot spot is a certain area that experiences a greater amount of generated heat as compared to other areas of the first die 110. The hot spots of the first die 110 may correspond to the locations of the pillars 515 coated with the powder layer 5151 illustrated in FIG. 1G. However, other distribution of the hot spots may be possible. In order to prevent malfunction of the device package 100 resulted from overheating, an effective manner for dissipating heat from the dies (e.g., 110 and 120) is important.

Still referring to FIG. 2A, the package component 130 may be or include a package substrate, where the conductive patterns are embedded in laminated dielectric layers. In some embodiments, the package component 130 is a built-up package substrate with (or without) a core layer. In some embodiments, the package component 130 is a multiple-layered circuit board (e.g., a printed circuit board (PCB)) or other types of substrates, depending on product requirements. In some embodiments, the package component 130 includes a first side 130a, a second side 130b opposite to the first side 130a, and a sidewall 130s connected to the first side 130a and the second side 130b. The package component 130 may include contact pads 132 distributed at the first side 130a. The die connectors (112 and 122) of the first and second dies (110 and 120) may be in physical and electrical contact with the contact pads 132. In some embodiments, the external terminals 134 are formed on the second side 130b of the package component 130. The first and second dies (110 and 120) may be electrically coupled to the external terminals 134 through the package component 130. The external terminals 134 may be or include solder balls, ball grid array (BGA), metal pillars, or another suitable connectors, and may be made of conductive materials, such as solder, copper, gold, silver, metal alloy, combinations thereof, or any suitable conductive materials. The external terminals 134 may be configured to be electrically coupled to another package component (see FIG. 3) and to transport signals (and/or power) to/from the package component.

Referring to FIG. 2B and with reference to FIG. 2A, a ring structure 210 may be attached to the device package 100 through an adhesive layer 212. For example, the adhesive layer 212 is formed on a predetermined location of the package component 130. For example, the adhesive layer 212 is formed as a continuous (or discontinuous) ring along the periphery of the first side 130a of the package component 130. The first and second dies (110 and 120) may be encircled within a region defined by the adhesive layer 212. In some embodiments, an adhesive material is dispensed and then cured to harden the adhesive layer 212. The curing temperature and duration may be dependent on the material chosen for the adhesive layer 212. The adhesive layer 212 may be any suitable non-conductive adhesive (e.g., a silicone-based adhesive, an epoxy-resin-based adhesive, an acrylic-based material, etc.), conductive adhesive, attach film, or the like. It is noted that any suitable adhesive material, any suitable method of application, and any suitable thickness may be used for the adhesive layer 212.

With continued reference to FIG. 2B, the ring structure 210 may include a first side 210a and a second side 210b opposite to the first side 210a, where the adhesive layer 212 is on the first side 210a. A combination of the ring structure 210 and the adhesive layer 212 may have an overall height H21 measured between the second side 210b and the first side 130a. The overall height H21 may be greater than the overall height H12 measured between the second side 120b of the respective second die 120 and the first side 130a. The overall height H21 may be greater than the overall height H11 measured between the second side 110b and the first side 130a. The ring structure 210 may be configured as a stiffener ring for constraining the package component 130 to minimize warpage (e.g., caused by stress generated during subsequent processing steps) and/or to enhance the robustness of the device package 100. The ring structure 210 may counter-balance the forces exerted by the CTE mismatch between the elements included in the device package 100.

In some embodiments, the ring structure 210 is placed over the blank area of the package component 130 to laterally surround the first die 110 encapsulated with the insulating encapsulation 115 and also surround the second dies 120 disposed at opposing sides of the first die 110. For example, the ring structure 210 is a single piece and includes one or more hollow region(s) for accommodating the first die 110 and the second dies 120 therein. Alternatively, the ring structure 210 includes discrete segments arranged around the first die 110 and the second dies 120. The material(s) of the ring structure 210 may (or may not) be thermal conductive, depending on product requirements. Examples of the material(s) of the ring structure 210 include copper, aluminum, cobalt, nickel, stainless steel, tungsten, a copper-tungsten alloy, a copper-molybdenum alloy, silver diamond, copper diamond, metal diamond composites, aluminum nitride, aluminum silicon carbide, an iron-nickel alloy, the like, combinations thereof, etc. The ring structure 210 may provide a rigidifying structure for the resulting package assembly and/or may be formed in any desirable shape and/or may include any desirable pattern for accommodating the dies on the package component 130.

Referring to FIG. 2C and with reference to FIG. 2B, the VC lid 500 may be attached to the ring structure 210 through an adhesive layer 214 to form a package assembly 10. The VC lid 500 may be disposed over the first and second dies (110 and 120) and may be thermally coupled to the first and second dies (110 and 120) through a thermal interface material (TIM) layer 216. The VC lid 500 is the same as the VC lid 500 described in FIGS. 1A-1G, and thus the details thereof are not repeated herein. The maximum thickness H0 (see FIG. 1A) of the VC lid 500 may be greater than the overall height H11 measured between the second side 110b and the first side 130a. The adhesive layer 214 may be formed on the second side 210b of the ring structure 210. The adhesive layer 214 may (or may not) be thermally conductive. The material(s) of the adhesive layer 214 may be similar to the material of the adhesive layer 212. The TIM layer 216 may be formed on the second side 120b of the respective second die 120 and may also be formed on the second side 110b of the first die 110 (and the upper surface 115b of the insulating encapsulation 115, if desired). The TIM layer 216 and the adhesive layer 212/214 may be of different materials. The TIM layer 216 may be dispensed in a grease form, a gel form, a paste form, etc., and then cured during the attachment of the VC lid 500. The TIM layer 216 may be replaced with a thermal conductive gel/grease which includes a polymeric material, solder paste, or the like. Other suitable thermal conductive material(s) may be used to thermally couple the VC lid 500 to the first die 110.

With continued reference to FIG. 2C, the ring structure 210 may be attached to the lower portion 510 of the VC lid 500, and the ring structure 210 with the adhesive layer 214 may be located within the grooves (e.g., 5111V and 5112V). The grooves (e.g., 5111V and 5112V) may be formed at the locations that will not affect the thermal-dissipating connection between the dies (e.g., 110 and 120) and the VC lid 500. In some embodiments, the second dies 120 overlap the first region R1 of the VC lid 500, and the first die 110 encapsulated with the insulating encapsulation 115 overlaps the second region R2 of the VC lid 500. In some embodiments, each of the protrusions 5111P within the first region R1 is directly over one of the second dies 120 and is thermally coupled to the one of the second dies 120 through the TIM layer 216. In some embodiments, the protrusion 5112P within the second region R2 is directly over the first die 110 encapsulated with the insulating encapsulation 115 and is thermally coupled to the first die 110. The pillars 513 coated with the powder layer 5131 and/or the pillars 514 distributed within the first region R1 may be directly over the second dies 120. The pillars 515 coated with the powder layer 5151 and the pillars 516 distributed within the second region R2 may be directly over the first die 110. In an embodiment, the pillars 515 coated with the powder layer 5151 and the pillars 516 arranged in a denser manner may help spread the heat generated from the hot spots of the first die 110. In this manner, heat generated from the first and second dies (110 and 120) may be more effectively transferred to the heat-dissipating component (see FIG. 3) through the VC lid 500 and the TIM layer 216, and malfunction of the device package 100 resulted from overheating may be prevented.

FIG. 3 is a schematic cross-sectional view of a package module, in accordance with some embodiments. Unless specified otherwise, the components in FIG. 3 are essentially the same as the like components, which are denoted by like reference numerals in the embodiments in FIGS. 1A-2C. In FIG. 3, a functional flow of the VC Lid 500 during operation is discussed. Referring to FIG. 3 and with reference to FIG. 2C, a package module 1000 including the package assembly 10 coupled to a heat-dissipating component 400 is provided. The package assembly 10 is the same as the package assembly 10 discussed in FIG. 2C, and thus the details thereof are not repeated herein. In some embodiments, the package assembly 10 is disposed on and electrically coupled to a package component 300. For example, the external terminals 134 of the package assembly 10 are in physical and electrical contact with the package component 300. The package component 300 may be or include a package substrate, an interposer, a printed circuit board, a mother board, and/or the like.

In some embodiments, the heat-dissipating component 400 is disposed on the VC lid 500 and thermally coupled to the VC lid 500 through a TIM layer 218. The heat-dissipating component 400 may be or include a heat spreader, a heat sink, a heat pipe, a heat-dissipating fan, the like, a combination thereof, etc. The TIM layer 218 may be similar to the TIM layer 216 described in FIG. 2C, and thus the details thereof are not repeated herein. The package module 1000 may include fasteners 402 attaching the heat-dissipating component 400 to the package component 300. The fasteners 402 may include screws that extend through the heat-dissipating component 400 to threaded holes of the package component 300. Although the fasteners 402 are illustrated as screws herein, any suitable fasteners (e.g., clamps) may be used to attach the heat-dissipating component 400 to the package component 300.

With continued reference to FIG. 3 and FIG. 2C, during the operation of the package module 1000, the VC Lid 500 may work to disperse heat generated from the first and second dies (110 and 120) of the device package 100 through the TIM layer 216. As the VC Lid 500 operates and works to conduct heat away from the device package 100, the vapor chamber 530 is vacuumed and configured to carry heat from a heat source (e.g., hot spots of the dies) by evaporation of the working fluid 540. For example, during the operation of the device package 100, the working fluid 540 contained in the wicking structure 550 is heated and vaporizes by absorbing heat from the first and second dies (110 and 120), as indicated by the arrows AR1. In some embodiments, the heat generated by the respective second die 120 may be transferred to the upper portion 510 of the VC lid 500 through the pillars (513 and 514), as indicated by the arrows AR2. The heat generated by the first die 110 may be transferred to the upper portion 510 of the VC lid 500 through the pillars (515 and 516), as indicated by the arrows AR3. The pillars (515 and 516) arranged in a denser manner may provide increased effectiveness and efficiency of heat transfer away from the device package 100.

Still referring to FIG. 3 and FIG. 2C, the vapor of the working fluid 540 may spread to fill the vapor chamber 530. The vapor may travel to a cooler region, for example, to the mesh 522 and/or the top plate 521 of the upper portion 520 (as indicated by the arrows AR4). When the vapor of the working fluid 54 comes into contact with the upper portion 520, the vapor may condense back to the liquid form of the working fluid 540. The heat may thus be expelled through the surfaces of the vapor chamber 530. Once condensed, the working fluid 540 may return to the lower portion 520, as indicated by the arrows AR5. The powder layers (5131 and 5131) formed on the sidewalls of the pillars (513 and 515) may help accelerate the return flow of working fluid 540 through, for example, a capillary action. The working fluid 540 may frequently vaporize and condense to form a circulation to disperse the heat generated by the device package 100. This arrangement may effectively spread thermal energy across the VC Lid 500 so that heat generated by the device package 100 may be dissipated to the heat-dissipating component 400 and/or the surrounding environment in an efficient manner.

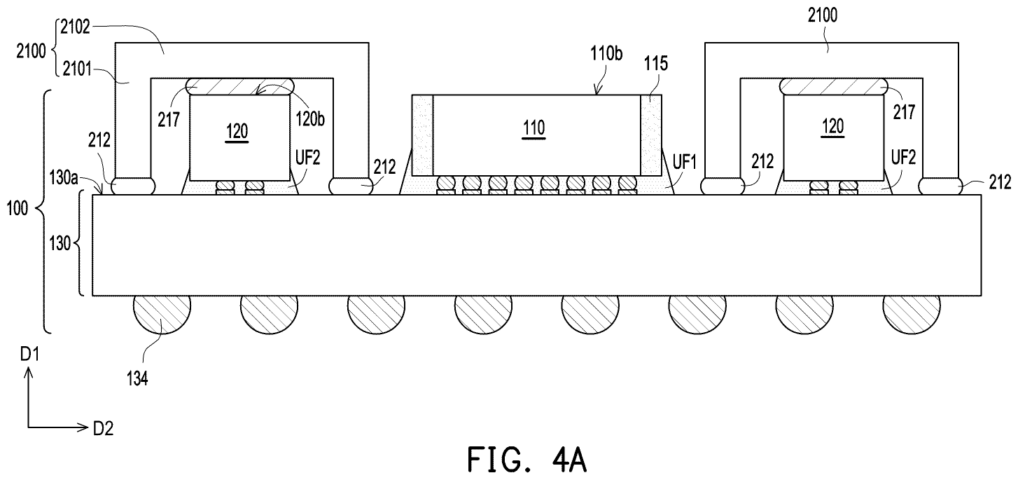

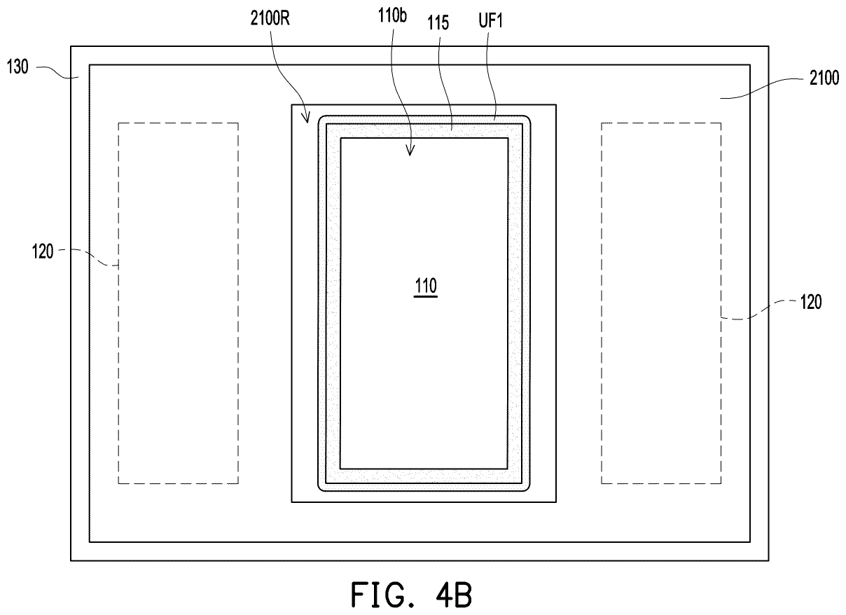

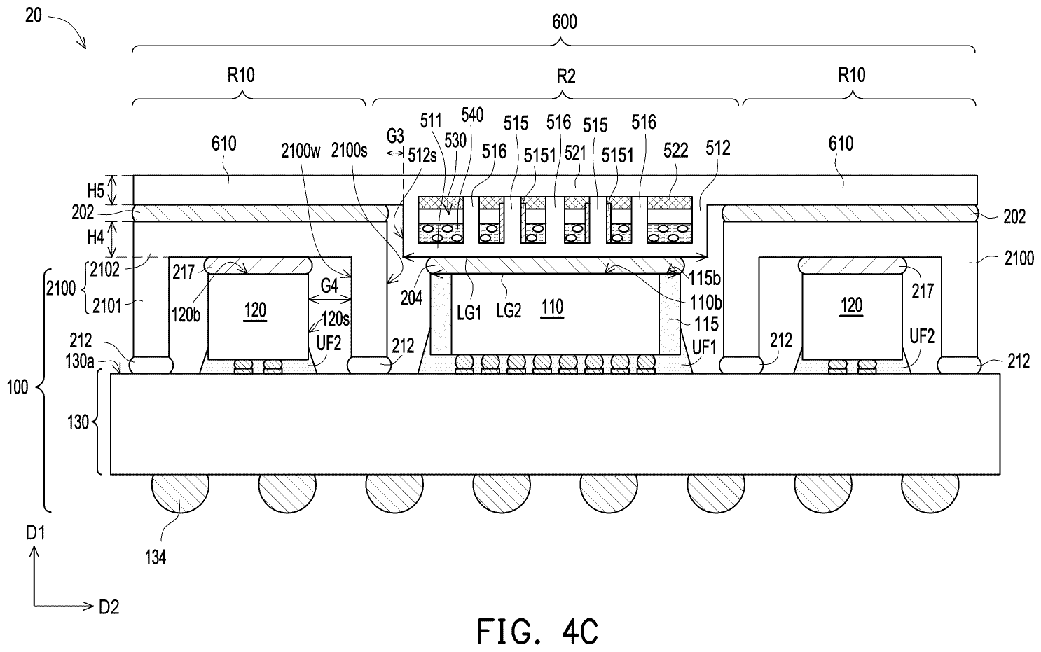

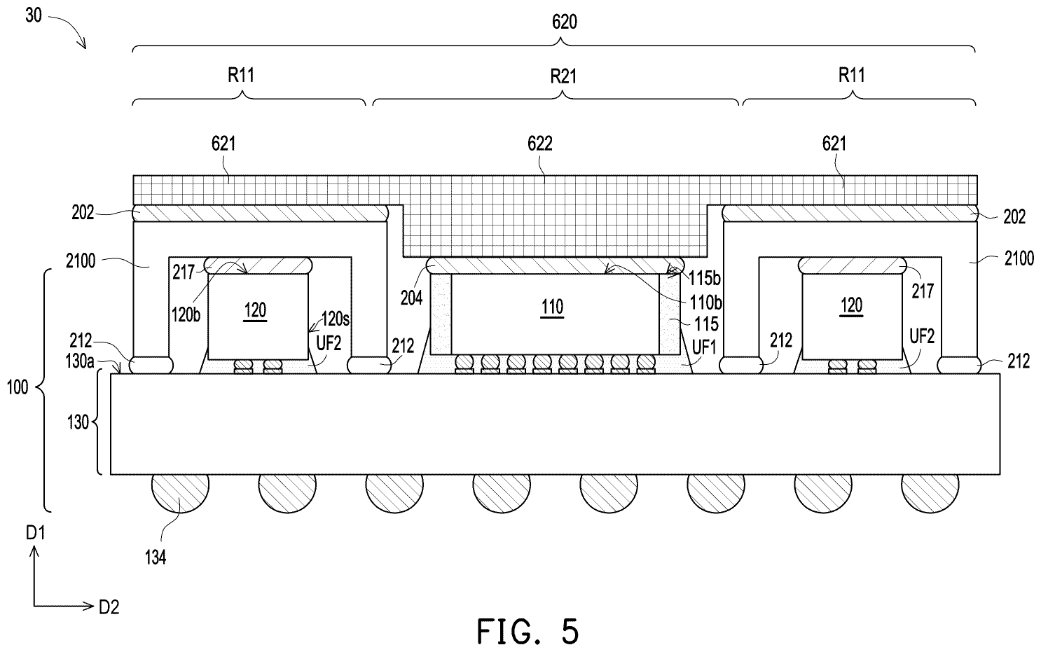

FIGS. 4A and 4C are schematic cross-sectional views of various stages of manufacturing a package assembly, and FIG. 4B is a schematic top view of the structure shown in FIG. 4A, in accordance with some embodiments. Like reference numbers are used to designate like elements. A variation to the VC lid will be described, and such variation is applicable to other embodiments described in the present disclosure.

Referring to FIG. 4A and with reference to FIG. 2B, the structure shown in FIG. 4A is similar to the structure shown in FIG. 2B, except that the second dies 120 are housed within a ring structure 2100. By accommodating the second dies 120 in the ring structure 2100, the design of heat dissipation to the first die 110 may be more flexible. The difference between the ring structure 2100 and the ring structure 210 shown in FIG. 2B lies in that the ring structure 2100 further includes a plate portion 2102 disposed over the second side 120b of the respective second die 120. The plate portion 2102 may extend along the second direction D2 and connected to the leg portion 2101 extending along the first direction D1. The leg portion 2101 may be attached to the package component 130 through the adhesive layer 212. After the attachment of the ring structure 2100, a cavity is formed to accommodate the second dies 120 therein. In some embodiments, the plate portion 2102 is attached to the second side 120b of the respective second die 120 through a TIM layer 217. The TIM layer 217 may be similar to the TIM layer 216 described in FIG. 2C. In an embodiment, the TIM layer 217 is replaced with an adhesive layer similar to the adhesive layer 212. Alternatively, the TIM layer 217 is omitted.

Referring to FIG. 4B and with reference to FIG. 4A, in the top view, the boundary of the ring structure 2100 may be fully within the boundary of the package component 130. The ring structure 2100 may include a hollow region 2100R accessibly exposing the first die 110, the insulating encapsulation 115 laterally covering the first die 110, and the underfill layer UF1 (if exists) surrounding the insulating encapsulation 115. The first die 110 may be laterally encircled by the ring structure 2100. In the top view, the second dies 120 are fully shielded by the ring structure 2100, and thus the second dies 120 are illustrated in the dashed lines to indicate they are underneath the ring structure 2100. Note that some elements (e.g., the underfill layer UF2, the adhesive layer 212, the TIM layer 217, etc.) are not illustrated in FIG. 4B.

Referring to FIG. 4C and with reference to FIG. 4A and FIG. 2C, a VC lid 600 may be attached to the ring structure 2100 and the first die 110 to form a package assembly 20. For example, the VC lid 600 includes a first region R10 and the second region R2 surrounded by the first region R10, where the first region R10 is attached to the plate portion 2102 of the ring structure 2100 through a TIM layer 202, and the second region R2 is attached to the second side 110b of the first die 110 and the upper surface 115b of the insulating encapsulation 115 through a TIM layer 204. In some embodiments, the TIM layer 204 includes a phase (or state) change material which is adapted to change phase (or state) such as between a film and a pad or between a solid material to a softer material. For example, the TIM layer 204 is adapted to change phase (or state) at a set temperature ranging from about 40° C. to about 60° C. The TIM layer 204 may include paraffin wax, alkyl hydrocarbons, amorphous ethylene propylene rubber, thin metal pad alloy of tin, indium, bismuth, etc. The TIM layer 204 may include polymer component, amorphous polymer matrix, silicone-organic block copolymer, thermally conductive fillers, treating agents, an antioxidant, the like, combinations thereof, etc. The polymer chains of the TIM layer 204 may provide enhanced stability of thermal filler dispersion during both the solid and softened states due to its long chain formulation.

In an embodiment, the thickness of the TIM layer 204 changes upon application of heat. For example, during operation, the heat generated from the first die 110 dissipates through the TIM layer 204 to the VC lid 600. As the TIM layer 204 is exposed to an increase in temperature, the TIM layer 204 may change phase (or state) to become a thin film. As the device temperature cools down, the TIM layer 204 may transform back to the non-phase change state (e.g., to become a thicker pad as compared to the thin film state upon application of heat). The thickness difference between two states (e.g., the film state and the pad state) of the TIM layer 204 may be in a range of about 10 m and about 100 m. Other phase changes (e.g., between solid and a liquid, a liquid and a gas, or a solid and a gas, etc.) may take place during the heating and cooling of the hot spot(s), depending on the material properties of the TIM layer 204. The TIM layer 202 may have a material similar to the TIM layer 204. The TIM layer 202 and/or the TIM layer 204 may be replaced with the TIM layer 216 described in FIG. 2C.

With reference to FIG. 4C, the configuration of the second region R2 of the VC lid 600 may be similar to that of the second region R2 of the VC lid 500 described in FIG. 1A. In some embodiments, the second region R2 has a lateral dimension LG1 measured along the second direction D2, and a combination of the second side 110b and the upper surface 115b has a lateral dimension LG2. The lateral dimension LG1 may be greater than (or substantially equal to) the lateral dimension LG2. In the second region R2, the VC lid 600 may be configured to vaporize the working liquid 540 as a vapor and condense the vapor to the liquid form, during the operation of the package assembly 20. The functional flow of the VC Lid 600 in the second region R2 is similar to that of the VC lid 500 described in FIG. 3, and thus the details thereof are not repeated herein. The difference between the VC lid 600 and the VC lid 500 includes that the vapor chamber 530 is only disposed in the second region R2 and does not extend to the first region R1. The VC Lid 600 includes a plate portion 610 in the first region R1, where the plate portion 610 may surround and be connected to the chamber wall 512 in the second region R2. The plate portion 610 may be attached to the underlying plate portion 2102 of the ring structure 2100 through the TIM layer 202. The material of the plate portion 610 may be selected from the same candidate material(s) for forming the bottom plate 511 described in FIG. 1A.

Still referring to FIG. 4C, the plate portion 2102 of the ring structure 2100 may have a thickness H4 measured along the first direction D1, where the thickness H4 may range from about 0.5 mm to about 2.0 mm. The plate portion 610 of the VC lid 600 may have a thickness H5 measured along the first direction D1, where the thickness H5 may range from about 0.5 mm to about 3.0 mm. In some embodiments, the thickness H5 is greater than the thickness H4. It is realized that the thicknesses are merely examples and may be changed to other suitable values. In some embodiments, a gap is between an outer sidewall 512s of the chamber wall 512 and a sidewall 2100s of the ring structure 2100 closest to the outer sidewall 512s, where the gap is a non-zero gap which has a lateral dimension G3 measured along the second direction D2. The lateral dimension G3 may be in a range of about 0.3 mm to about 3.0 mm. In an embodiment, the gap having the lateral dimension G3 is an air gap. In some embodiments, a gap is between an inner sidewall 2100w of the ring structure 2100 and the sidewall 120s of the respective second die 120 facing the inner sidewall 2100w, where the gap has a lateral dimension G4 measured along the second direction D2. The lateral dimension G4 may be in a range of about 0.3 mm to about 5.0 mm. In an embodiment, the gap having the lateral dimension G4 is an air gap. The package assembly 20 may have a different configuration than shown.

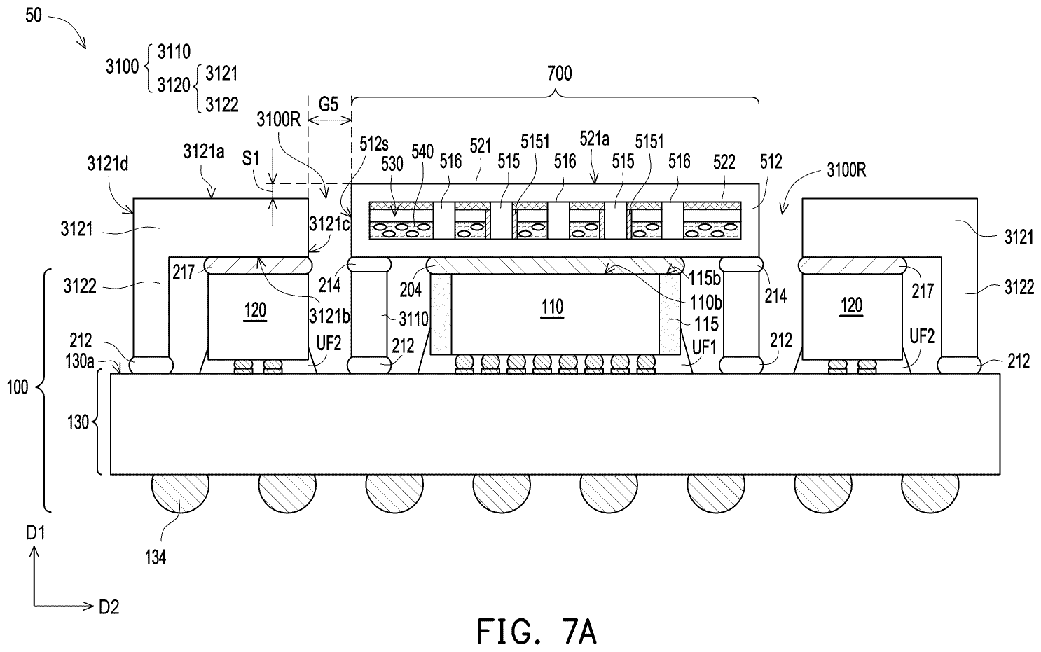

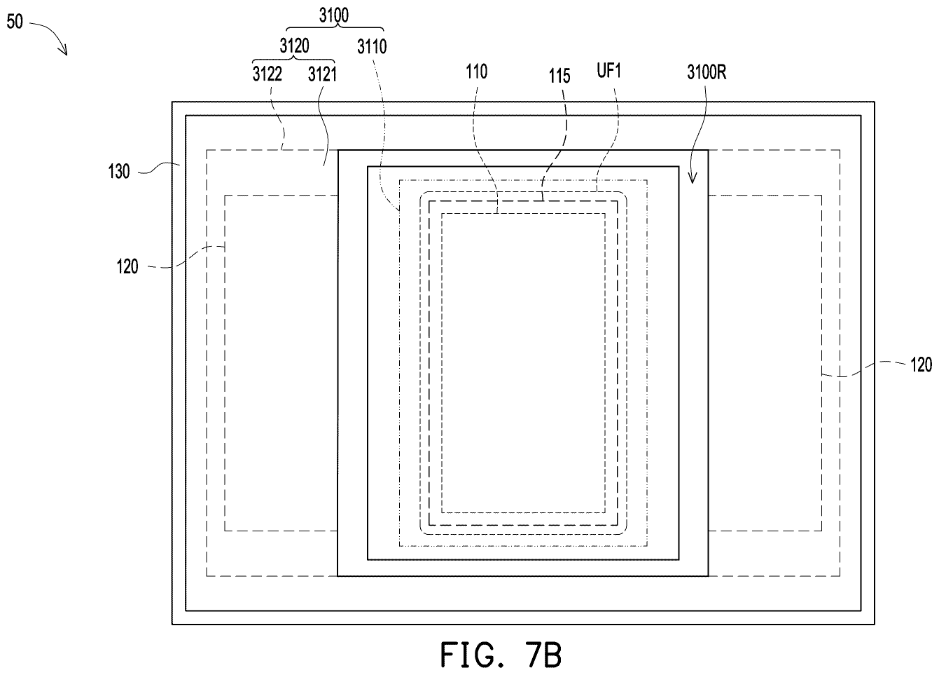

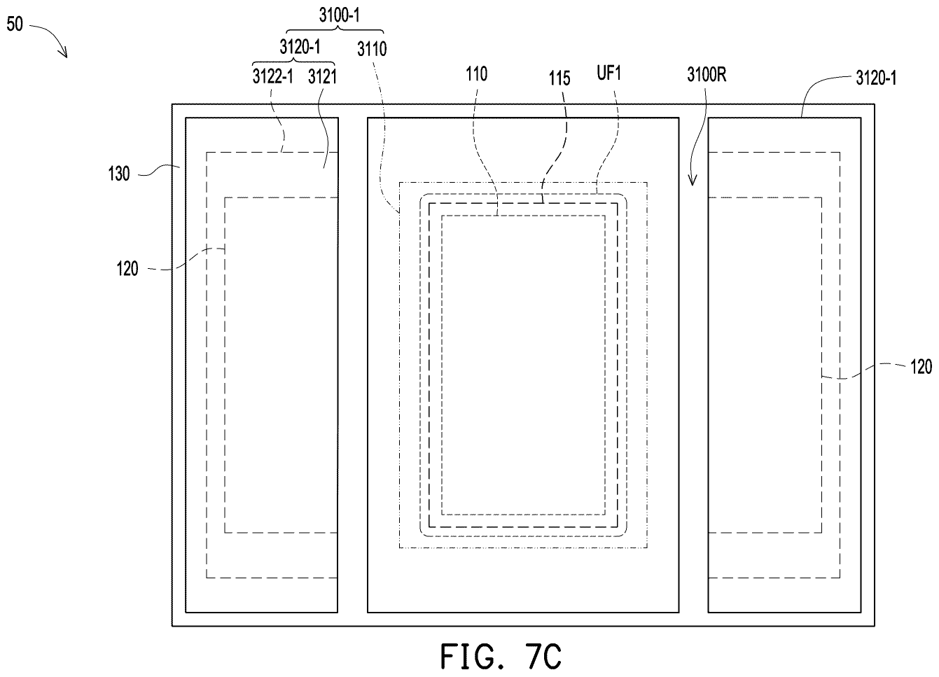

FIGS. 5, 6, and 7A are schematic cross-sectional views of variations of a package assembly, in accordance with some embodiments. FIGS. 7B and 7C are schematic top view of variations of the package assembly shown in FIG. 7A, in accordance with some embodiments. Like reference numbers are used to designate like elements. A variation to the lid (e.g., the VC lid or the heat-dissipating lid) will be described, and such variation is applicable to other embodiments described in the present disclosure.

Referring to FIG. 5 and with reference to FIG. 4C, a package assembly 30 illustrated in FIG. 5 is similar to the package assembly 20 described in FIG. 4C, and thus the details thereof are not repeated herein. For example, the VC lid 600 of the package assembly 20 shown in FIG. 4C is replaced with a heat-dissipating lid 620 to form the package assembly 30. The shape, the dimension, and the configuration of the heat-dissipating lid 620 may be similar to those of the VC lid 600. For example, the heat-dissipating lid 620 includes a first region R11 surrounding and connected to a second region R21, where the first region R11 overlaps the ring structure 2100 and the second dies 120 housed in the ring structure 2100, and the second region R21 overlaps the first die 110 and the insulating encapsulation 115 laterally covering the first die 110. The heat-dissipating lid 620 may include a plate portion 621 in the first region R11 and a protrusion 622 in the second region R21 and connected to the plate portion 621. The thickness of the plate portion 621 measured along the first direction D1 may be less than the thickness of the protrusion 622 measured along the first direction D1.

The heat-dissipating lid 620 may include one or more high thermal conductive material(s) such as copper, aluminum, cobalt, copper coated with nickel, stainless steel SUS430, tungsten, copper-tungsten, copper-molybdenum, silver diamond, copper diamond, metal diamond composites, aluminum nitride, aluminum silicon carbide, alloy 42, diamond like carbon, single crystal diamond, the like, combinations thereof, etc. The thermal conductivity of the material(s) of the heat-dissipating lid 620 may range from about 200 W/mK to about 3000 W/mK. It is realized that the thermal conductivities are merely examples and may be changed to other suitable values. The first and second dies (110 and 120) may be thermally coupled to the heat-dissipating lid 620 through the TIM layers (204 and 202). The heat-dissipating lid 620 may help spread the heat generated from the device package 100 over a larger area. In some embodiments, during the operation of the package assembly 30, the heat generated from the first and/or second dies (110 and/or 120) is dissipated to another heat-dissipating component (see FIG. 3) or to surrounding environment through the heat-dissipating lid 620.

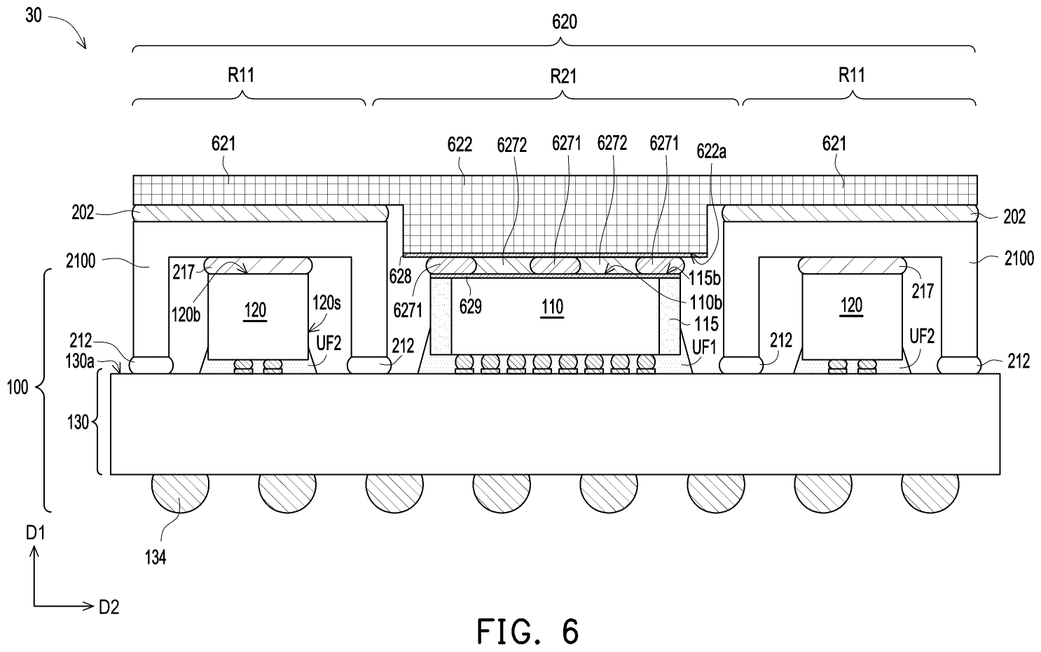

Referring to FIG. 6 and with reference to FIG. 5, a package assembly 40 illustrated in FIG. 6 is similar to the package assembly 30 described in FIG. 5, and the difference therebetween lies in the thermally conductive connections between the protrusion 622 and the first die 110. In some embodiments, a metallic layer 629 is formed on the second side 110b of the first die 110. The metallic layer 629 may extend to cover the upper surface 115b of the insulating encapsulation 115. The metallic layer 629 may include one or more conductive material(s) such as titanium, copper, nickel, vanadium, aluminum, cobalt, gold, silver, stainless steel, the like, combinations thereof, or other suitable conductive material(s) having relatively high thermal conductivities. In some embodiments, a metallic layer 628 partially (or fully) covers a lower surface 622a of the protrusion 622 facing the first die 110. The material(s) of the metallic layer 628 may be selected from the candidate material(s) for forming the metallic layer 629.

In some embodiments, a TIM structure 627 is interposed between the metallic layers (628 and 629) in the first direction D1 and is thermally coupled to the metallic layers (628 and 629). For example, the TIM structure 627 includes metallic portions 6271 and phase change portions 6272 laterally connected to the metallic portions 6271. The metallic portions 6271 may include indium, gallium, tin, silver, gold, copper, bismuth, zinc, the like, combinations thereof, etc. The metallic portions 6271 may be provided in gel form or in sheet form. The phase change portions 6272 may have different material properties than the metallic portions 6271. The material(s) of the phase change portions 6272 may be similar to that of the TIM layer 204 described in FIG. 4C. For example, the metallic portions 6271 have a higher thermal conductivity than the thermal conductivity of the phase change portions 6272. In some embodiments, the metallic portions 6271 are disposed directly over the hot spot(s) of the first die 110. The phase change portions 6272 may be disposed at the locations that are not occupied by the metallic portions 6271. It is appreciated the metallic TIM layer generally has higher Young's modulus, which may induce crack or delamination between the first die 110 and the TIM structure. By forming the metallic TIM as discontinuous portions (i.e. the metallic portions 6271) and filling the rest area with the phase change portions 6272, the TIM structure 627 may facilitate the heat dissipation of the first die 110, and crack and/or delamination may be reduced. It is realized that the phase change portions 6272 and the metallic portions 6271 may have a different configuration than shown.

Referring to FIGS. 7A-7C and with reference to FIG. 4C, a package assembly 50 illustrated in FIG. 7A is similar to the package assembly 20 described in FIG. 4C, and the difference therebetween includes a VC lid 700 and a ring structure 3100. The VC lid 700 of the package assembly 50 may be similar to the VC lid 600, except that the first region R10 of the VC lid 600 is omitted and only the second region R2 remains disposed over the first die 110. The structure of the VC lid 700 is similar to the structure described in the second region R2 of the VC lid 600, and thus the details thereof are not repeated herein. In some embodiments, the ring structure 3100 of the package assembly 50 includes an inner portion 3110 disposed around the first die 110 and an outer portion 3120 laterally surrounding the inner portion 3110. The material(s) of the ring structure 3100 may be similar to the ring structure 2100 described in FIG. 4C.

In an embodiment, the inner portion 3110 of the ring structure 3100 fully encircles the insulating encapsulation 115 (and the underfill layer UF1, if exists), as shown in the top views of FIGS. 7B-7C. The inner portion 3110 may provide adequate mechanical support to the VC lid 700. In some embodiments, the inner portion 3110 is attached to the bottom plate 511 of the VC lid 700 through the adhesive layer 214. For example, the adhesive layer 214 is disposed on the peripheral region of the bottom plate 511, and the TIM layer 204 is disposed on the central region of the bottom plate 511, where the first die 110 is thermally coupled to the VC lid 700 through the TIM layer 204. The ring structure 3100 may include a hollow region 3100R accessibly exposing the first die 110, the insulating encapsulation 115, and the underfill layer UF1 (if exist), as shown in the top views of FIGS. 7B-7C. Note that some elements (e.g., the underfill layer UF2, the adhesive layers (212 and 214), the TIM layers (217 and 204), etc.) are not illustrated in the top views of FIGS. 7B-7C.

With continued reference to FIG. 7A, the outer portion 3120 of the ring structure 3100 may include a plate portion 3121 directly over the second dies 120 and a leg portion 3122 connected to the plate portion 3121 and laterally surrounding the second dies 120. In some embodiments, the plate portion 3121 includes a first side 3121a, a second side 3121b opposite to the first side 3121a and attached to the respective second die 120 through the TIM layer 217, an inner sidewall 3121c facing the VC lid 700 and connected to the first side 3121a and the second side 3121b, and an outer sidewall 3121E opposite to the inner sidewall 3121c. In some embodiments, the first side 521a of the top plate 521 of the VC lid 700 is higher than the first side 3121a of the plate portion 3121 of the ring structure 3200, relative to the first side 130a of the package component 130. For example, a vertical distance S1 between the first side 3121a and a virtual plane on which the first side 521a is located is non-zero. The vertical distance S1 measured along the first direction D1 may be in a range of about 0.1 mm and about 1.0 mm. In some embodiments, a lateral distance G5 is between the inner sidewall 3121c of the plate portion 3121 and the outer sidewall 512s of the chamber wall 512, where the lateral distance G5 is non-zero. For example, a non-zero gap is formed and has the lateral distance G5 measured along the second direction D2. The lateral distance G5 may be in a range of about 0.2 mm and about 2.0 mm. It is realized that the vertical and lateral distances are merely examples and may be changed to other suitable values.

With continued reference to FIGS. 7A-7C, the leg portion 3122 of the ring structure 3100 may extend along the first direction D1 and be connected to the second side 3121b of the plate portion 3121. In some embodiments, the leg portion 3122 is formed as a closed loop encircling the inner portion 3110, as shown in the top view of FIG. 7B. In some embodiments, the leg portion 3122 is replaced with a leg portion 3122-1. As shown in the top view of FIG. 7C, the leg portion 3122-1 of the outer portion 3120-1 of the ring structure 3100-1 has discontinuous and separate segments. For example, the discontinuous and separate segments of the leg portion 3122-1 are laterally spaced apart from one another by the inner portion 3110. It is realized that the variations to the ring structure are applicable to other embodiments described in the present disclosure.

Embodiments may have one or a combination of the following features and/or advantages. The package assembly includes the lid (e.g., the VC lid or the heat-dissipating lid) with improved heat dissipation efficiency configured to conduct heat out of the device package, and malfunction of the device package resulted from overheating may be prevented. For example, the temperature uniformity across the device package may be improved by about 30% to about 45%, as compared to the device package coupled to the conventional lid. The maximum operating temperature of the die (e.g., the high-power-consuming die, the high performance die, etc.) having hot spots may be lowered by about 10.8° C. to about 12.8° C., as compared to the device package coupled to the conventional lid. The VC lid may include pillars in the vapor chamber and distributed in a denser manner, and some of the pillars coated with the powder layer are disposed corresponding to the hot spots of the die. The pillars coated with the powder layer may facilitate accelerating the return flow of the working fluid, thereby improved the circulation rate of the working fluid in the vapor chamber. In this manner, the heat generated by the device package may be dissipated more efficiently. The VC lid may include larger pillars in the vapor chamber to reinforce the mechanical strength of the VC lid and reduce the likelihood of the pop-corning effect. The VC lid may include one or more groove(s) provide stress relief for stress incurred during the attachment of the VC lid.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments, a package assembly includes a device package, a ring structure, and a lid disposed on the ring structure. The device package includes a package substrate, a first die coupled to the package substrate, and a second die aside the first die and coupled to the package substrate. The ring structure is disposed on the package substrate and surrounds the first and second dies. The lid is at least thermally coupled to the first die. The lid includes a vapor chamber, a working fluid vaporizing and condensing to form a circulation in the vapor chamber, a wicking structure in the vapor chamber to transfer the working fluid, first pillars and second pillars distributed in the vapor chamber. The first pillars are coated with a first powder layer and disposed corresponding to hot spots of the first die. The second pillars are directly over the first die, where the first and second pillars are arranged in a staggered manner.

In accordance with some embodiments, a package assembly includes a device package, a ring structure, and a lid disposed on the ring structure. The device package includes a package substrate, a first die coupled to the package substrate, and a second die aside the first die and coupled to the package substrate. The ring structure includes a plate portion disposed over the second die a leg portion coupling the plate portion to the package substrate. The leg portion laterally surrounds the first and second dies. The lid is at least thermally coupled to the first die.

In accordance with some embodiments, a manufacturing method of a package assembly includes: forming a device package, where the device package includes a package substrate, a first die coupled to the package substrate, and a second die aside the first die and coupled to the package substrate; attaching a ring structure to the package substrate to surround the first and the second dies; and attaching a lid to the ring structure to at least thermally coupled to the first die, where the lid includes a vapor chamber, a working fluid vaporizing and condensing to form a circulation in the vapor chamber, a wicking structure in the vapor chamber to transfer the working fluid, first pillars and second pillars distributed in the vapor chamber. The first pillars are coated with a powder layer and disposed corresponding to hot spots of the first die. The second pillars are directly over the first die, where the first and second pillars are arranged in a staggered manner.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package assembly, comprising:
a device package comprising a package substrate, a first die coupled to the package substrate, and a second die aside the first die and coupled to the package substrate;
a ring structure disposed on the package substrate and surrounding the first and second dies; and
a lid disposed on the ring structure and at least thermally coupled to the first die, the lid comprising:
a vapor chamber;
a working fluid in the vapor chamber;
a wicking structure in the vapor chamber;
first pillars distributed in the vapor chamber, coated with a first powder layer; and
second pillars distributed in the vapor chamber and directly over the first die, wherein the first and second pillars are arranged in a staggered manner.

2. The package assembly of claim 1, wherein the lid further comprises a top plate and a mesh covering an inner surface of the top plate, wherein the mesh, the inner surface of the top plate, the first pillars, and the second pillars are bonded together.

3. The package assembly of claim 1, wherein the lid further comprises:
a bottom plate comprising protrusions and a groove surrounding the protrusions, wherein each of the protrusions are attached to one of the first and second dies, and the ring structure is disposed within the groove.

4. The package assembly of claim 1, wherein the lid further comprises:
third pillars distributed in the vapor chamber, coated with a second powder layer, and disposed around an array of the first and second pillars; and
fourth pillars distributed in the vapor chamber, disposed between the third pillars, and over the second die.

5. The package assembly of claim 4, wherein a distribution density of the first and second pillars are greater than a distribution density of the third and fourth pillars.

6. The package assembly of claim 4, wherein lateral dimensions of the third and fourth pillars are greater than lateral dimensions of the first and second pillars.

7. The package assembly of claim 1, wherein the lid further comprises:
a plate portion directly over and thermally coupled to the second die; and
a chamber wall connected to the plate portion and enclosing the vapor chamber, wherein a non-zero gap is between an outer sidewall of the chamber wall and a sidewall of the ring structure facing the chamber wall.

8. The package assembly of claim 7, wherein the ring structure comprises:
a plate portion attached to a back side of the second die; and
a leg portion coupling the plate portion to the package substrate, laterally surrounding the second die, and laterally between the first and second dies.

9. The package assembly of claim 8, wherein a thickness of the plate portion of the lid is greater than a thickness of the plate portion of the ring structure.

10. The package assembly of claim 1, wherein:
the lid further comprises a chamber wall enclosing the vapor chamber, and
the ring structure comprises:
an inner portion coupling the lid to the package substrate; and
an outer portion laterally aside the inner portion and the second die, and the outer portion being spatially separated from the lid by a non-zero gap.

11. The package assembly of claim 10, wherein an upper surface of the lid is higher than an upper surface of the outer portion of the ring structure, relative to a side of the package substrate.

12. The package assembly of claim 10, wherein the outer portion of the ring structure comprises a plate attached to a back side of the second die and a leg coupling the plate to the package substrate, wherein the leg is formed as a closed loop on the package substrate in a top view.

13. The package assembly of claim 10, wherein the outer portion of the ring structure comprises a plate attached to a back side of the second die and a leg coupling the plate to the package substrate, wherein the leg comprises discontinuous segments laterally separated from each other by the lid in a top view.

14. The package assembly of claim 1, further comprising:
a thermal interface material (TIM) layer disposed between and thermally coupled to the first die and the lid, and the TIM layer comprising a material changing thickness upon application of heat to the lid.

15. A package assembly, comprising:
a device package comprising a package substrate, a first die coupled to the package substrate, and a second die aside the first die and coupled to the package substrate;
a ring structure comprising:
a plate portion disposed over the second die; and
a leg portion coupling the plate portion to the package substrate and laterally surrounding the first and second dies; and
a lid disposed on the ring structure and at least thermally coupled to the first die.

16. The package assembly of claim 15, wherein the plate portion of the ring structure comprises a hollow region within which the first die and the lid are disposed.

17. The package assembly of claim 15, further comprising:
a thermal interface material (TIM) structure disposed between and thermally coupled to the lid and the first die, the TIM structure comprises:
metallic portions disposed over hot spots of the first die;
phase change portions connected to the metallic portions and comprising a material changing between a film form and a pad form upon application of heat to the lid, wherein the phase change portions in the film form are thinner than in the pad form.

18. The package assembly of claim 15, wherein the lid comprises:
a chamber wall enclosing a vapor chamber;
a working fluid vaporizing and condensing to form a circulation in the vapor chamber;
a wicking structure in the vapor chamber to transfer the working fluid;
pillars distributed in the vapor chamber and over the first die, at least a portion of the pillars being coated with a powder layer, wherein material of the powder layer and the portion of the pillars are the same.

19. A manufacturing method of a package assembly, comprising:
forming a device package, wherein the device package comprises a package substrate, a first die coupled to the package substrate, and a second die aside the first die and coupled to the package substrate;
attaching a ring structure to the package substrate to surround the first and the second dies; and
attaching a lid to the ring structure to at least thermally coupled to the first die, wherein the lid comprises:
a vapor chamber;
a working fluid vaporizing and condensing to form a circulation in the vapor chamber,
a wicking structure in the vapor chamber to transfer the working fluid;
first pillars distributed in the vapor chamber, coated with a powder layer, and disposed corresponding to hot spots of the first die; and
second pillars distributed in the vapor chamber and directly over the first die, wherein the first and second pillars are arranged in a staggered manner.

20. The manufacturing method of claim 19, wherein after attaching the ring structure to the package substrate, the second die is housed within the ring structure.
